(19) United States
(12) Patent Application Publication
(10) Pub. No.: US 2025/0095744 A1
(43) Pub. Date: Mar. 20, 2025

(54) MEMORY DEVICE, OPERATION METHOD THEREOF, AND MEMORY SYSTEM

(71) Applicant: YANGTZE MEMORY TECHNOLOGIES CO., LTD., Wuhan (CN)

(72) Inventors: Jiameng CUI, Wuhan (CN); Jianquan JIA, Wuhan (CN); Kaikai YOU, Wuhan (CN); Junbao WANG, Wuhan (CN); Wenhao XIONG, Wuhan (CN); Wei QI, Wuhan (CN); An ZHANG, Wuhan (CN)

(21) Appl. No.: 18/409,089

(22) Filed: Jan. 10, 2024

(30) Foreign Application Priority Data
Sep. 20, 2023 (CN) 2023112202215

(51) Int. Cl. G11C 16/10; G11C 16/08; G11C 16/28

(52) U.S. Cl. CPC G11C 16/102; G11C 16/08; G11C 16/28

(57) ABSTRACT

A memory device includes a memory cell array having stacked first and second memory decks; and a peripheral circuit coupled to the memory cell array and configured to: when performing a program operation on a selected memory cell layer in the first memory deck, apply a voltage to a word line layer corresponding to the selected memory cell layer and apply a first voltage to a word line layer corresponding to an unselected memory cell layer in the first memory deck; apply a second voltage to the word line layer corresponding to the plurality of memory cell layers in the second memory deck; and apply a third voltage to the dummy word line layer corresponding to the at least one dummy memory cell layer at the junction position of the first memory deck and the second memory deck. The first voltage exceeds the second voltage, which exceeds the third voltage.

### CROSS-REFERENCE TO RELATED APPLICATIONS

The present application claims priority to Chinese Patent Application No. 2023112202215, which was filed Sep. 20, 2023, is titled “MEMORY DEVICE AND ITS OPERATING METHOD, MEMORY SYSTEM,” and is hereby incorporated herein by reference in its entirety.

### TECHNICAL FIELD

The examples of the present application relate to the technical field of semiconductors, and in particular to a memory device and an operation method thereof and a memory system.

### BACKGROUND

As the number of stacked layers of a three-dimensional memory device (e.g., 3D NAND flash memory) increases and a channel length becomes longer, the program voltage disturbance (Vpgm disturb) and the pass voltage disturbance (Vpass disturb) become larger while a program crase read (PER) operation is performed.

### SUMMARY

In one aspect, the examples of the present disclosure provide a memory device comprising: a memory cell array comprising a first memory deck and a second memory deck stacked and provided adjacent to each other, wherein the first memory deck and the second memory deck both comprise a plurality of memory cell layers and a word line layer corresponding to each memory cell layer, and at least one dummy memory cell layer and a dummy word line layer corresponding to each dummy memory cell layer are provided at a junction position of the first memory deck and the second memory deck; and a peripheral circuit coupled to the memory cell array and configured to: when performing a program operation on a selected memory cell layer in the first memory deck, apply a program voltage to a word line layer corresponding to the selected memory cell layer and apply a first pass voltage to a word line layer corresponding to an unselected memory cell layer in the first memory deck; apply a second pass voltage to the word line layer corresponding to the plurality of memory cell layers in the second memory deck; and apply a third pass voltage to the dummy word line layer corresponding to the at least one dummy memory cell layer at the junction position of the first memory deck and the second memory deck, wherein the third pass voltage is less than the second pass voltage, and the second pass voltage is less than the first pass voltage.

In some examples, a difference between the first pass voltage and the second pass voltage is a first difference, and a difference between the second pass voltage and the third pass voltage is a second difference, wherein the first difference is different from the second difference.

In some examples, the second difference is greater than the first difference.

In some examples, the plurality of memory cell layers in the second memory deck are in a programmed state.

In some examples, the unselected memory cell layer in the first memory deck comprises a memory cell layer in a programmed state and a memory cell layer in an erased state, and the first pass voltage comprises a first sub-pass voltage and a second sub-pass voltage, wherein the peripheral circuit is configured to: apply the first sub-pass voltage to a word line layer corresponding to the memory cell layer in the programmed state; and apply the second sub-pass voltage to a word line layer corresponding to the memory cell layer in the erased state, wherein the first sub-pass voltage is different from the second sub-pass voltage.

In some examples, the memory cell array further comprises a third memory deck stacked with both the first memory deck and the second memory deck, wherein the third memory deck is provided adjacent to the first memory deck, at least one dummy memory cell layer and a dummy word line layer corresponding to each dummy memory cell layer are provided at a junction position of the third memory deck and the first memory deck, and the peripheral circuit is configured to apply the third pass voltage to the dummy word line layer corresponding to the at least one dummy memory cell layer at the junction position between the first memory deck and the third memory deck; or the third memory deck is provided adjacent to the second memory deck, at least one dummy memory cell layer and a dummy word line layer corresponding to each dummy memory cell layer are provided at a junction position of the third memory deck and the second memory deck, and the peripheral circuit is configured to apply the second pass voltage to the dummy word line layer corresponding to the at least one dummy memory cell layer at the junction position between the second memory deck and the third memory deck.

In some examples, the at least one dummy memory cell layer and the dummy word line layer corresponding to each dummy memory cell layer at the junction position of the first memory deck and the second memory deck belong to at least one of the first memory deck or the second memory deck.

In some examples, the at least one dummy word line layer at the junction position of the first memory deck and the second memory deck comprises a first dummy word line layer located in the first memory deck and a second dummy word line layer located in the second memory deck, and the third pass voltage comprises a third sub-pass voltage and a fourth sub-pass voltage, wherein the peripheral circuit is configured to apply the third sub-pass voltage to the first dummy word line layer and apply the fourth sub-pass voltage to the second dummy word line layer, wherein the third sub-pass voltage is different from the fourth sub-pass voltage.

In some examples, the peripheral circuit is configured to: when performing a program operation on the plurality of memory cell layers in the first memory deck, perform a sequential program operation or a reversed program operation on the plurality of memory cell layers in the first memory deck.

In the second aspect, the examples of present application provide a memory system comprising: one or more memory devices according to any one of above examples; and a memory controller coupled to the memory devices and configured to control the memory devices.

In the third aspect, the examples of the present application provide an operation method of a memory device, comprising: when performing a program operation on a selected memory cell layer in a first memory deck of a memory cell array of the memory device, applying a program voltage to a word line layer corresponding to the selected memory cell layer and applying a first pass voltage to a word line layer corresponding to an unselected memory cell layer in the first memory deck; applying a second pass voltage to a word line layer corresponding to a plurality of memory cell layers in a second memory deck which is stacked and provided adjacent to the first memory deck; and applying a third pass voltage to a dummy word line layer corresponding to at least one dummy memory cell layer at a junction position of the first memory deck and the second memory deck, wherein the third pass voltage is less than the second pass voltage, and the second pass voltage is less than the first pass voltage.

In some examples, the unselected memory cell layer in the first memory deck comprises a memory cell layer in a programmed state and a memory cell layer in an erased state, and the first pass voltage comprises a first sub-pass voltage and a second sub-pass voltage, wherein the applying a first pass voltage to a word line layer corresponding to an unselected memory cell layer in the first memory deck comprises: applying the first sub-pass voltage to a word line layer corresponding to the memory cell layer in the programmed state; and applying the second sub-pass voltage to a word line layer corresponding to the memory cell layer in the erased state, wherein the first sub-pass voltage is different from the second sub-pass voltage.

In some examples, the memory cell array comprises a third memory deck stacked with both the first memory deck and the second memory deck, wherein when the third memory deck is provided adjacent to the first memory deck, at least one dummy memory cell layer and a dummy word line layer corresponding to each dummy memory cell layer are provided at a junction position of the third memory deck and the first memory deck, and the operation method further comprises applying the third pass voltage to the dummy word line layer corresponding to the at least one dummy memory cell layer at the junction position between the first memory deck and the third memory deck; or when the third memory deck is provided adjacent to the second memory deck, at least one dummy memory cell layer and a dummy word line layer corresponding to each dummy memory cell layer are provided at a junction position of the third memory deck and the second memory deck, and the operation method further comprises applying the second pass voltage to the dummy word line layer corresponding to the at least one dummy memory cell layer at the junction position between the second memory deck and the third memory deck.

In some examples, the at least one dummy word line layer at the junction position of the first memory deck and the second memory deck comprises a first dummy word line layer located in the first memory deck and a second dummy word line layer located in the second memory deck, and the third pass voltage comprises a third sub-pass voltage and a fourth sub-pass voltage, wherein the applying a third pass voltage to a dummy word line layer corresponding to at least one dummy memory cell layer at a junction position of the first memory deck and the second memory deck comprises: applying the third sub-pass voltage to the first dummy word line layer and applying the fourth sub-pass voltage to the second dummy word line layer, wherein the third sub-pass voltage is different from the fourth sub-pass voltage.

In some examples, the method further comprises: when performing a program operation on the plurality of memory cell layers in the first memory deck, performing a sequential program operation or a reversed program operation on the plurality of memory cell layers in the first memory deck.

### BRIEF DESCRIPTION OF THE DRAWINGS

FIG. 1 is a schematic circuit diagram of an example memory device including a peripheral circuit and a memory cell array according to some examples of the present application;

FIG. 2 is a schematic circuit diagram of an example memory cell array according to some examples of the present application;

FIG. 3A is a schematic cross-sectional view of a first example memory cell array according to some examples of the present application;

FIG. 3B is a schematic cross-sectional view of a second example memory cell array according to some examples of the present application;

FIG. 4A is a first example programming scheme for a multi-memory deck memory device according to some examples of the present application;

FIG. 4B is a schematic diagram of a signal waveform of the first example programming scheme of FIG. 4A;

FIG. 4C is a schematic diagram of a channel potential of the first example programming scheme of FIG. 4A;

FIG. 5A is a second example programming scheme for a multi-memory deck memory device according to some examples of the present application;

FIG. 5B is a schematic diagram of a signal waveform of the second example programming scheme of FIG. 5A;

FIG. 5C is a schematic diagram of a channel potential of the second example programming scheme of FIG. 5A;

FIG. 6A is a third example programming scheme for a multi-memory deck memory device according to some examples of the present application;

FIG. 6B is a schematic diagram of a signal waveform of the third example programming scheme of FIG. 6A;

FIG. 6C is a schematic diagram of a channel potential of the third example programming scheme of FIG. 6A;

FIG. 7A is a fourth example programming scheme for a multi-memory deck memory device according to some examples of the present application;

FIG. 7B is a schematic diagram of a signal waveform of the fourth example programming scheme of FIG. 7A;

FIG. 7C is a schematic diagram of a channel potential of the fourth example programming scheme of FIG. 7A;

FIG. 8 is a schematic diagram of an example system having a memory system according to an example of the present application;

FIG. 9 is a schematic diagram of an example memory card having a memory system according to an example of the present application;

FIG. 10 is a schematic diagram of an example solid-state driver having a memory system according to an example of the present application.

### DETAILED DESCRIPTION

The technical solutions in the examples of the present application will be described clearly and completely in the following in conjunction with the examples of the present application and the accompanying drawings, and it is obvious that the described examples are only a part of the examples of the present application, but not all of the examples. Based on the examples in the present application, all other examples obtained by a person of ordinary skill in the art without creative labor fall within the scope of protection of the present application.

In the following description, numerous specific details are given in order to provide a more thorough understanding of the present application. It will be apparent, however, to one skilled in the art that the present application may be practiced without one or more of these details. In other examples, some technical features well-known in the art are not described to avoid confusion with the present disclosure; that is, not all features of the actual example are described here, and well-known functions and structures are not described in detail.

In the drawings, the size of layers, regions, elements and their relative sizes may be exaggerated for clarity. Like reference numerals refer to like elements throughout.

It will be understood that when an element or layer is referred to as being “on,” “adjacent to,” “connected to” or “coupled to” other elements or layers, it can be directly on, adjacent to, connected to, or coupled to other elements or layers, or intervening elements or layers may be present. In contrast, when an element is referred to as being “directly on,” “directly adjacent to,” “directly connected to” or “directly coupled to” other elements or layers, there are no intervening elements or layers. It will be understood that, although the terms such as first, second, third, etc. may be used to describe at least one of various elements, components, regions, layers or sections, at least one of these elements, components, regions, layers or sections should not be limited by these terms. These terms are only used to distinguish one element, component, region, layer or section from another clement, component, region, layer or section. Thus, a first element, component, region, layer or section discussed below could be represented as a second element, component, region, layer or section without departing from the teachings of the present application. When a second element, component, region, layer or section is discussed, it does not indicate that a first element, component, region, layer or section exists in the present disclosure.

Spatial relationship terms such as “under”, “below”, “beneath”, “underneath”, “on”, “above” and so on, can be used here for convenience to describe the relationship between one clement or feature and other elements or features shown in the figures. It will be understood that the spatially relationship terms also comprise different orientations of the device in use and operation in addition to the orientation depicted in the figures. For example, if the device in the figures is turned over, elements or features described as “below” or “underneath” or “under” other elements or features would then be oriented as “above” the other elements or features. Thus, the example terms “below” and “under” can comprise both orientations of above and below. The device may be otherwise oriented (rotated 90 degrees or at other orientations) and the spatial descriptors used herein may be interpreted accordingly.

The terminology used herein is for the purpose of describing particular examples only and is not to be taken as a limitation of the present disclosure. As used herein, “a”, “an” and “said/the” in singular forms are intended to include the plural forms as well, unless the context clearly dictates otherwise. It should also be understood that at least one of the terms “consists of” or “comprising”, when used in this specification, identify the presence of at least one of stated features, integers, operations, clements or components, but do not exclude presence or addition of at least one of one or more other features, integers, operations, elements, components or groups. As used herein, the term “at least one of . . . ” includes any and all combinations of the associated listed items.

In order to provide a thoroughly understanding of the present application, the detailed operations and structure are described below in order to illustrate the technical solution of the present application. Detailed description of examples of the present application is as follows. However, in addition to these detailed descriptions, the present application may have other examples.

In various examples of the present application, a memory device includes a first memory deck and a second memory deck provided adjacent to each other. When the PER operation is independently performed on the selected memory deck (the first memory deck), the unselected word line layer of the selected memory deck needs to be maintained at a higher pass voltage (the first pass voltage) to increase the boosting potential of the selected word line layer of the selected memory deck, thus to suppress program voltage disturbance. The unselected word line layer of the unselected memory deck (the second memory deck) needs to be maintained at a lower pass voltage (the second pass voltage which is smaller than the first pass voltage) to reduce the pass voltage disturbance of the unselected word line layer of the unselected memory deck. Meanwhile, the pass voltage (the third pass voltage which is smaller than the second pass voltage) of the dummy memory layer group at the junction position adjacent to the selected memory deck is further reduced, thus a soft cut voltage may be formed between the memory layer group of the selected memory deck and the memory layer group of the unselected memory deck adjacent to the selected memory deck, and a potential barrier for the channel residual electrons is formed to suppress the migration of the channel residual electrons to the channel position corresponding to the selected word line layer of the memory layer group of the selected memory deck, so that a higher boosting potential is maintained in the channel corresponding to the selected word line layer of the memory layer group of the selected memory deck to suppress the program voltage disturbance. That is, in the examples of the present application, when the PER operation is independently performed on each memory deck, the pass voltage disturbance of the unselected memory deck is reduced while the program voltage disturbance of the selected memory deck is suppressed.

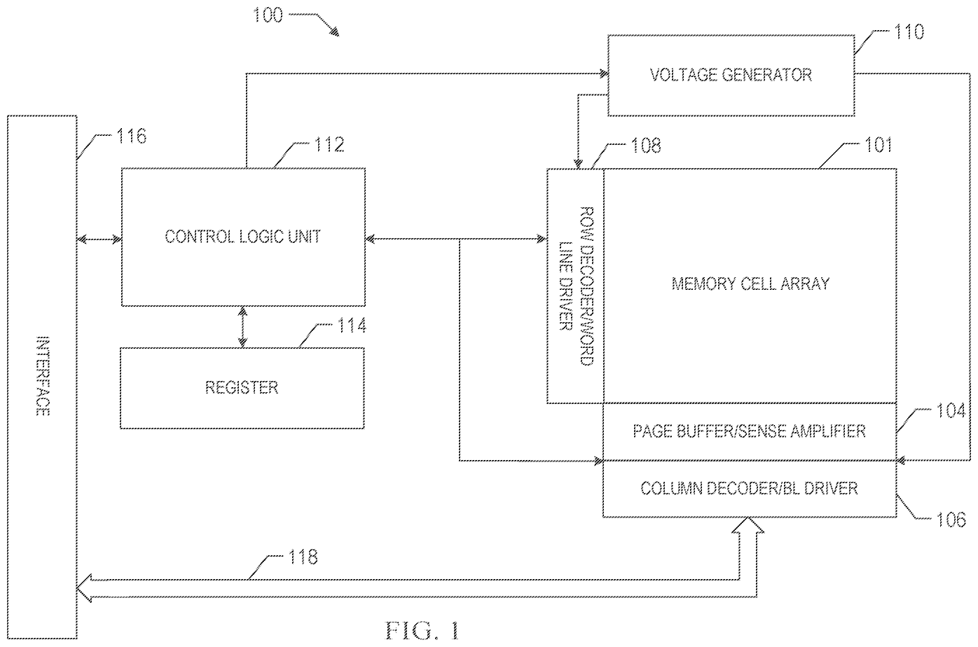

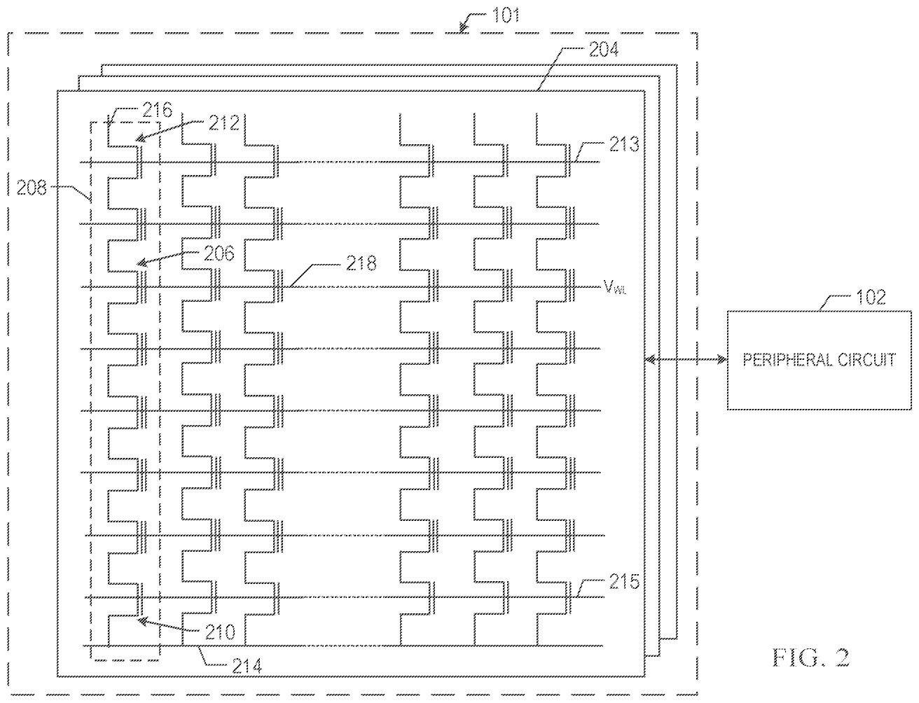

FIG. 1 is a schematic circuit diagram of an example memory device including a peripheral circuit and a memory cell array in accordance with some examples of the present application. FIG. 2 is a schematic circuit diagram of an example memory cell array according to some examples of the present application. FIGS. 1 and 2 illustrate some example peripheral circuits 102 and memory cell arrays 101 which will be described below in conjunction with FIGS. 1 and 2.

Referring to FIGS. 1 and 2, the peripheral circuit 102 may include a page buffer/sense amplifier 104, a column decoder/bit line driver 106, a row decoder/word line driver 108, a voltage generator 110, a control logic unit 112, a register 114, an interface 116, and a data bus 118. It should be understood that additional peripheral circuits not shown in FIG. 1 may also be included in some examples.

Page buffer/sense amplifier 104 can be configured to read and program (write) data from and to memory cell array 101 according to the control signals from the control logic unit 112. In one example, page buffer/sense amplifier 104 may store a page of program data (write data) to be programmed into a page of the memory cell array 101. In another example, page buffer/sense amplifier 104 may perform program verify operations to ensure that the data has been properly programmed into memory cells 206 coupled to selected word lines (WL) 218. In still another example, page buffer/sense amplifier 104 may also sense the low power signals from bit line (BL) 216 that represents a data bit stored in memory cell 206 and amplify the small voltage swing to recognizable logic levels in a read operation. Column decoder/bit line driver 106 can be configured to be controlled by control logic unit 112 and select one or more NAND memory strings 208 by applying bit line voltages generated from voltage generator 110.

Row decoder/word line driver 108 can be configured to be controlled by control logic unit 112 and select/deselect blocks 204 of memory cell array 101 and select/deselect word lines 218 of block 204. Row decoder/word line driver 108 can be further configured to drive word lines 218 using word line voltages generated from voltage generator 110. In some examples, row decoder/word line driver 108 can also select/deselect and drive bottom selective gate (BSG) lines 215 and top selective gate (TSG) lines 213 as well. As described below in detail, row decoder/word line driver 108 is configured to perform program operations on the memory cells 206 coupled to the selected word line(s) 218. Voltage generator 110 can be configured to be controlled by control logic unit 112 and gencrate the word line voltages (e.g., read voltage, program voltage, pass voltage, local voltage, verify voltage, etc.), bit line voltages, and source line voltages to be supplied to memory cell array 101.

In some examples, the program operation may include a plurality of operations. As an example, the program operation may include a bit line setting operation, a program executing operation and a program recovery operation. After the program operation is performed, it is needed perform a program verify operation; and after the program verify operation is performed, it is also needed to perform a program verify recovery operation.

In performing the bit line setting operation of the program operation, the voltage of the unselected word line may be maintained at the ground voltage GND. In performing the program executing operation of the program operation, a pass voltage Vpass may be applied to the unselected word line (hereinafter also referred to as unselected word line/unselect word line), and a program voltage Vpgm may be applied to the selected word line (hereinafter also referred to as the selected word line/select word line). Therefore, the memory cells connected to the selected word lines May be programmed. In performing the program recovery operation of the program operation, the voltages applied to all word lines may be reduced to the ground voltage GND. In performing the program verify operation, a verify voltage Vvrf may be applied to the selected word line, and a pass voltage Vpass may be applied to the unselected word line. In performing the program verify recovery operation, a recovery operation may be performed on both the unselected word line and the selected word line to reduce the voltage to the ground voltage GND.

The control logic unit 112 may be coupled to each of the peripheral circuits described above and configured to control the operation of each of the peripheral circuits. Registers 114 can be coupled to control logic unit 112 and include status registers, command registers, and address registers for storing status information, command operation codes (OP codes), and command addresses for controlling the operations of each peripheral circuit. Interface 116 may be coupled to control logic unit 112 and act as a control buffer to buffer and relay control commands received from a host (not shown) to control logic unit 112, and to buffer and relay status information received from control logic unit 112 to the host. Interface 116 may further be coupled to column decoder/bit line driver 106 via data bus 118 and act as a data I/O interface and data buffer to buffer and relay data to or from memory cell array 101.

Referring to FIG. 2, the memory device may include a memory cell array 101 and a peripheral circuit 102 coupled to the memory cell array 101. The memory cell array 101 may be illustrated as example of a 3D NAND type memory array, in which memory cells 206 are provided in the form of an array of NAND memory strings 208 each extending vertically above a substrate (not shown). In some examples, each NAND memory string 208 includes a plurality of memory cells 206 coupled in series and stacked vertically. Each memory cell 206 can hold a continuous, analog value, such as an electrical voltage or charge, that depends on the number of electrons trapped within a region of the memory cell 206. Each memory cell 206 can be either a floating gate type of memory cell including a floating-gate transistor or a charge trap type of memory cell including a charge-trap transistor.

In some examples, each memory cell 206 is a single-level cell (SLC) that has two possible memory states and thus, can store one bit of data, i.e., one memory cell stores 1 bit of data. Thus, each memory cell has two states, i.e., 0 and 1. For example, the first memory state “0” can correspond to a first range of voltages, and the second memory state “1” can correspond to a second range of voltages. In some examples, each memory cell 206 is a multi-level cell that is capable of storing more than a single bit of data in more than four memory states. For example, the MLC can store two bits per cell, three bits per cell (also known as Trinary-Level cell (TLC)), four bits per cell (also known as a Quad-Level cell (QLC)). In SLC mode, a memory cell stores 1 bit and has two logical states (“states”), i.e., states ER and P1. In MLC mode, a memory cell stores 2 bits and has four states, i.e., states ER, P1, P2 and P3. In TLC mode, a memory cell stores 3 bits and has eight states, i.e., state ER and states P1-P7. In QLC mode, a memory cell stores 4 bits and has 16 states.

As shown in FIG. 2, each NAND memory string 208 can include a BSG 210 at its source end and a TSG 212 at its drain end. BSG 210 and TSG 212 can be configured to activate selected NAND memory strings 208 during read and program operations. In some examples, the sources of NAND memory strings 208 in the same block 204 are coupled through the same source line (SL) 214, e.g., a common SL. In other words, all NAND memory strings 208 in the same block 204 have an array common source (ACS), according to some examples. TSG 212 of each NAND memory string 208 is coupled to a respective bit line 216 from which data can be read or written via an output bus (not shown), according to some examples. In some examples, each NAND memory string 208 is configured to be selected or deselected by at least one of: applying a select voltage (e.g., above the threshold voltage of the transistor having TSG 212) or a deselect voltage (e.g., 0 V) to respective TSG 212 through one or more TSG lines 213 or applying a select voltage (e.g., above the threshold voltage of the transistor having BSG 210) or a deselect voltage (e.g., 0 V) to respective BSG 210 through one or more BSG lines 215.

As shown in FIG. 2, NAND memory strings 208 can be organized into multiple blocks 204, each of which can have a common source line 214, e.g., coupled to the ground. In some examples, each block 204 is the basic data unit for erase operations, i.e., all memory cells 206 on the same block 204 are erased at the same time. To crase memory cells 206 in a selected block 204, source lines 214 coupled to selected block 204 as well as unselected blocks in the same plane as selected block 204 can be biased with an erase voltage (Vers), such as a high positive voltage (e.g., 20 V or more). It is understood that in some examples, erase operation may be performed at a half-block level, a quarter-block level, or a level having any suitable number of blocks or any suitable fractions of a block. The memory cells 206 of adjacent NAND memory strings 208 may be coupled by word lines 218, and the word lines 218 may be biased coupled to the selected word line with read and program voltage VwL (for example, a read voltage (e.g., 0.3V), a program voltage (e.g., 3V)) to select which row of memory cells 206 is affected by read and program operations.

With reference to FIGS. 1 and 2. in some examples, the peripheral circuit 102 may be coupled to the memory array 201 through bit line 216, word line 218, source line 214, BSG line 215 and TSG line 213. The peripheral circuit 102 may include any suitable analog, digital and mixed signal circuit for facilitating the operation of memory array 201 by applying at least one of voltage or current signal to and from each target memory cell 206 via bit line 216, word line 218, source line 214, BSG line 215 and TSG line 213.

In some examples, the peripheral circuit 102 may provide a waveform of the programming scheme to each target memory cell 206 by applying a word line bias voltage V_{WL} by the row decoder/word line driver 108. In some examples, the word line bias voltage V_{WL} applied to the word line 218 may include a program voltage Vpgm, a pass voltage Vpass and a cut voltage Vcut and the like. In some examples, the column decoder/bit line driver 106 may select or deselect the NAND memory string 208 (and its memory cells 206) by applying a select voltage or deselect voltage to the respective drain selective transistor 212 via the respective bit line 216 for various memory operations, such as programming of the selected memory cells 206.

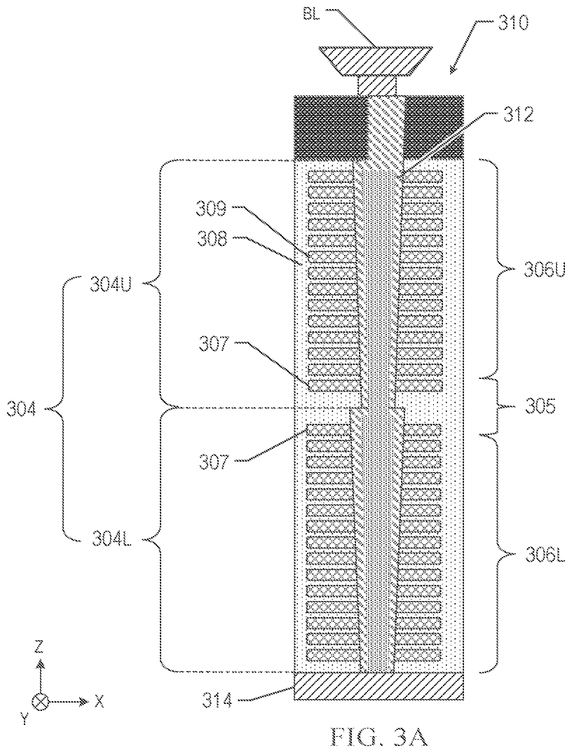

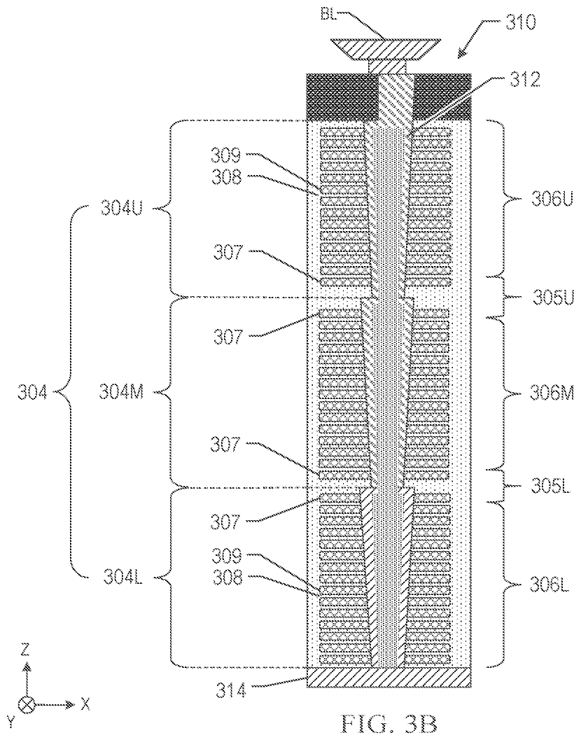

FIG. 3A is a schematic cross-sectional view of a first example memory cell array according to some examples of the present application. FIG. 3B is a schematic cross-sectional view of a second example memory cell array according to some examples of the present application.

Referring to FIGS. 3A and 3B, the memory cell array includes a NAND memory string 310 (e.g., NAND memory string 208 in FIG. 2) extending vertically over a substrate 314. The substrate 314 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

For case of description of examples of the present application, a first direction and a second direction are represented herein and hereafter as two orthogonal directions parallel to the top surface of the substrate, and a third direction is a direction perpendicular to the top surface of the substrate or a direction parallel to the thickness of the substrate. As an example, the first direction may be represented as the X direction in the drawings; the second direction may be represented as the Y direction in the drawings; and the third direction may be represented as the Z direction in the drawings. It should be noted that the X direction, Y direction and Z direction are included in FIGS. 3A and 3B to further illustrate the spatial relationship between the components in the memory cell array. The substrate includes two horizontal surfaces (e.g., a top surface and a bottom surface) extending horizontally in the X direction (i.e., a horizontal direction). As used herein, when the substrate is in the lowest plane of the semiconductor structure (e.g., the memory cell array) in the Z direction (i.e., the vertical direction or depth direction), whether one component of a semiconductor structure is “on”, “above” or “below” another component is determined relative to the substrate of the semiconductor structure in the Z direction. The same concepts will be applied throughout this application to describe spatial relations.

A NAND memory string 310 as shown in FIGS. 3A and 3B extends vertically over a substrate 314 through a memory stack layer 304 having alternately stacked gate layers 309 (also referred to herein as “word line layers 309”) and insulating layers 308.

The number of pairs of gate layer 309 and insulating layer 308 in memory stack layer 304 (e.g., 32, 64, 96 or 128) determines the number of memory cells in the memory cell array. Each gate layer 309 may include conductive materials, including but not limited to tungsten (W), cobalt (Co), copper (Cu), aluminum (Al), polysilicon, doped silicon, silicide or any combination thereof. In some examples, each gate layer 309 may include a metal layer, for example, a tungsten layer. In some examples, each gate layer 309 may include a doped polysilicon layer. Each gate layer 309 may include a control gate that surrounds the memory cells (e.g., the memory cell 206 in FIG. 2) of the NAND memory string 310 and may extend laterally as a word line (e.g., the word line 218 in FIG. 2).

Referring to FIGS. 3A and 3B, the NAND memory string 310 includes a channel structure 312 extending vertically through the memory stack layer 304. The NAND memory may select/deselect the NAND memory string 310 (e.g., the NAND memory string 208 in FIG. 2) via the BSG line (e.g., BSG line 215 in FIG. 2) and the TSG line (e.g., TSG line 213 in FIG. 2), wherein the TSG line is coupled to the gate of the drain selective transistor of the NAND memory string 310, and the BSG line is coupled to the gate of the source selective transistor of the NAND memory string 310. In some examples, the drain selective transistor of each NAND memory string 310 is coupled to a respective bit line BL from which data may be read or written via an output bus (not shown). In some examples, the source selective transistors of NAND memory strings 310 in the same block are coupled to the same source line (e.g., source line 214 in FIG. 2).

In some examples, the channel structure may comprise a channel hole filled with semiconductor material(s) (e.g., as a semiconductor channel, not shown in FIGS. 3A and 3B) and dielectric material(s) (e.g., as a memory film, not shown in FIGS. 3A and 3B). In some examples, the semiconductor channel includes silicon, such as amorphous silicon, polycrystalline silicon, or monocrystalline silicon. In some examples, the memory film is a composite dielectric layer including a tunneling layer, a storage layer (also referred to as a “charge trap/storage layer”), and a blocking layer. The channel structure 312 may have a cylindrical shape (e.g., a pillar shape). According to some examples, the semiconductor channel, the tunneling layer, the storage layer and the blocking layer are radially arranged in this order from the center of the pillar toward the outer surface of the pillar. The material of the tunneling layer may include silicon oxide, silicon oxynitride, or any combination thereof. The material of the storage layer may include silicon nitride, silicon oxynitride, or any combination thereof. The material of the blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

In some examples, the NAND memory string 310 also includes a semiconductor plug (not shown in FIGS. 3A and 3B) located in a lower portion of the NAND memory string 310 (e.g., at a lower end thereof). The semiconductor plug may comprise a semiconductor material, such as monocrystalline silicon, grown epitaxially from a substrate in any suitable direction. The semiconductor plug is coupled to a portion of the channel of a source selective transistor (e.g., the source selective transistor 210 of FIG. 2) of the NAND memory string 310. In some examples, the NAND memory string 310 also includes a channel plug located in an upper portion of the NAND memory string 310 (e.g., at an upper end thereof). In some examples, the channel plug is coupled to the channel of a drain selective transistor (e.g., the drain selective transistor 212 of FIG. 2) of the NAND memory string 310. As used herein, when the substrate is placed in the lowest plane of the memory cell array, the “upper end” of a component (e.g., channel structure 312) is the end farther from the substrate in the Z direction, and the “lower end” of a component (e.g., channel structure 312) is the end closer to the substrate in the Z direction.

In some examples, the NAND memory string 310 includes a plurality of control gates (each being a part of the gate layer 309) for the memory cells of the NAND memory string 310. The gate layer 309 may include a plurality of control gates for a plurality of NAND memory strings 310, and may serve as a laterally extending word line ending at the edge of the memory stack layer 304. The word line may receive a word line bias voltage for controlling operations of the memory cell by for example read, crase and program operations. It should be understood that, although not shown in FIGS. 3A and 3B, additional components of the memory cell array may be formed, and the components including but not limited to gate line slit/source contact, local contact, interconnect layers, and the like.

In FIGS. 3A and 3B, the NAND memory string 310 includes a single-channel structure, which is also referred to as a single-cell formation structure. It should be understood that in other examples, the NAND memory string 310 may include two channel structures electrically connected through inter-deck plugs (not shown in FIGS. 3A and 3B), which is also referred to as a dual-cell formation structure.

Referring to FIGS. 3A and 3B, in some examples, the PER operation may be performed at a half block level, at a one third block level, or at a level having any suitable fractions of a block. In some examples, the memory stack layer 304 may have a multi-deck architecture, and the memory stack layer 304 may include multiple memory decks. For example, as shown in FIG. 3A, the memory stack layer 304 may have dual memory decks, including a lower memory deck 304L located above the substrate 314 and an upper memory deck 304U located above the lower memory deck 304L. For example, as shown in FIG. 3B, the memory stack layer 304 may further have three memory decks, including a lower memory deck 304L located above the substrate 314, a middle memory deck 304M located above the lower memory deck 304L, and an upper memory deck 304U located above the memory deck 304M.

In some examples, each memory deck includes multiple memory cell layers and a word line layer 309 corresponding to each memory cell layer. At least one dummy memory cell layer and a dummy word line layer 307 corresponding to each dummy memory cell layer are provided at a junction position of adjacent memory decks.

In some examples, the number of gate layers of each memory deck may be the same or different. Referring to FIG. 3B, in some examples, the number of gate layers 309 in each of lower memory deck 304L, middle memory deck 304M and upper memory deck 304U may be the same or different. Referring to FIG. 3B, in some examples, the number of dummy word line layers 307 in each of lower memory deck 304L, middle memory deck 304M and upper memory deck 304U may be the same or different.

In some examples, a dummy memory layer group is provided at the junction position of adjacent memory decks in the vertical direction. For example, as shown in FIG. 3A, a dummy memory layer group 305 is provided at the junction position of the lower memory deck 304L and the upper memory deck 304U in the vertical direction. For example, as shown in FIG. 3B, a lower dummy memory layer group 305L is provided at the junction position of the lower memory deck 304L and the upper memory deck 304U in the vertical direction, and an upper dummy memory layer group 305U is provided at the junction position of the middle memory deck 304M and the upper memory deck 304U.

Referring to FIGS. 3A and 3B, the memory stack layer 304 includes multiple memory decks, each of the memory decks includes multiple memory cell layers and a word line layer (hereinafter may be referred to as “memory layer group”) corresponding to each memory cell layer. At least one dummy memory cell layer and a dummy word line layer (hereinafter referred to as “dummy memory layer group”) corresponding to each dummy memory cell layer are provided at the junction position of two adjacent memory decks. That is, the memory stack layer 304 includes multiple memory layer groups and a dummy memory layer group between two adjacent memory layer groups. The memory layer group may include multiple memory layers, and each of the memory layers may include a memory cell layer and a word line layer 309 corresponding to a memory cell layer. The dummy memory layer group may include at least one dummy memory layer, and each dummy memory layer may include a dummy memory cell layer and a dummy word line layer 307 corresponding to a dummy memory cell layer. For example, as shown in FIG. 3A, the memory stack layer 304 includes an upper memory layer group 306U, a dummy memory layer group 305 and a lower memory layer group 306L. For example, as shown in FIG. 3B, the memory stack layer 304 includes an upper memory layer group 306U, an upper dummy memory layer group 305U, a middle memory layer group 306M, a lower dummy memory layer group 305L and a lower memory layer group 306L.

In some examples, the dummy memory layer may have the same physical structure as the memory layer, but have a different electrical configuration than the memory layer, and the memory cells coupled through the dummy memory layer are not used for storing data (i.e., as a dummy memory cell).

Due to the demand for large-capacity and low-cost storage media, in three-dimensional memory devices (such as 3D NAND flash memory), the number of stack layers is continuously increased to improve the storage density of blocks. The 3D NAND flash memory uses the blocks as the smallest unit for erase operations. A larger capacity of blocks will undoubtedly burden the system of data management and affect product performance. Therefore, it is necessary to consider dividing the blocks into multiple memory decks, and performing PER operations separately on each memory deck.

When dividing the blocks of 3D NAND flash memory into multiple memory decks, and performing PER operations separately on each memory deck, for example, when programming the selected memory deck, the pass voltage Vpass of the unselected word line of the unselected memory deck is reduced to reduce its pass voltage disturbance. When programming the selected memory deck, reducing the pass voltage of the unselected memory deck will cause a potential difference in the channel, drive the residual electrons in the channel to migrate to the channel position corresponding to the selected word line to which the program voltage Vpgm is applied, and reduce the boosting potential of the channel corresponding to the selected word line, thus causing new program voltage disturbance.

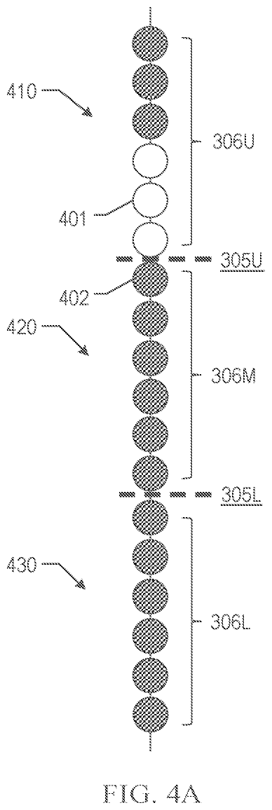

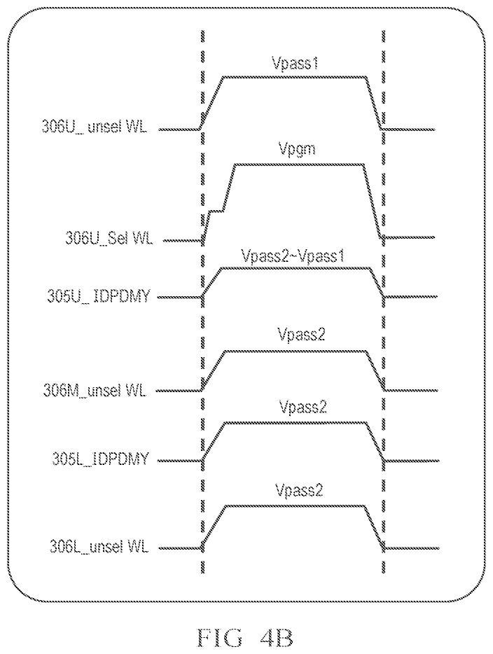

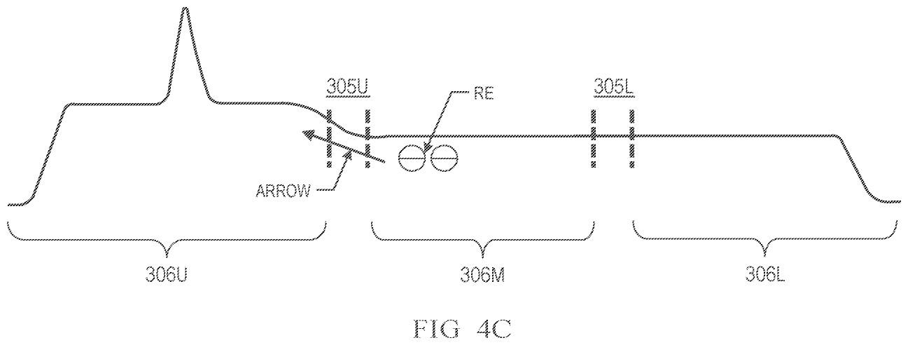

FIG. 4A is a first example programming scheme for a multi-memory deck memory device according to some examples of the present application. FIG. 4B is a schematic diagram of a signal waveform of the first example programming scheme of FIG. 4A. FIG. 4C is a schematic diagram of a channel potential of the first example programming scheme of FIG. 4A.

Referring to FIGS. 4A, 4B and 4C, and in combination with FIGS. 1, 2, 3A and 3B, in some examples, a memory device comprises: a memory cell array comprising a first memory deck and a second memory deck stacked and provided adjacent to each other, wherein the first memory deck and the second memory deck both comprise a plurality of memory cell layers and a word line layer corresponding to each memory cell layer, and at least one dummy memory cell layer and a dummy word line layer corresponding to each dummy memory cell layer are provided at a junction position of the first memory deck and the second memory deck; and a peripheral circuit coupled to the memory cell array and configured to: when performing a program operation on a selected memory cell layer in the first memory deck, apply a program voltage to a word line layer corresponding to the selected memory cell layer and apply a first pass voltage to a word line layer corresponding to an unselected memory cell layer in the first memory deck; apply a voltage Vpass2˜Vpass1 between the first pass voltage and the second pass voltage to a word line layer corresponding to a plurality of memory cell layers in the second memory deck; and apply a second pass voltage to the dummy word line layer corresponding to the at least one dummy memory cell layer at the junction position of the first memory deck and the second memory deck; wherein the second pass voltage is less than the first pass voltage.

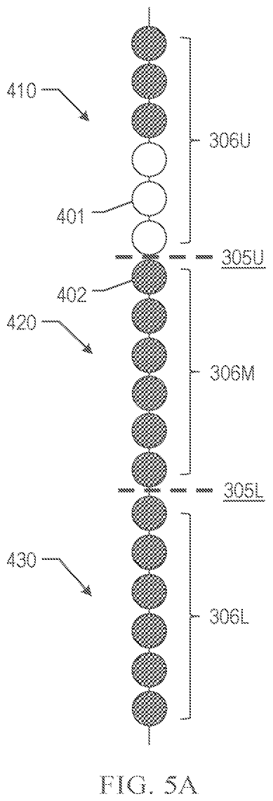

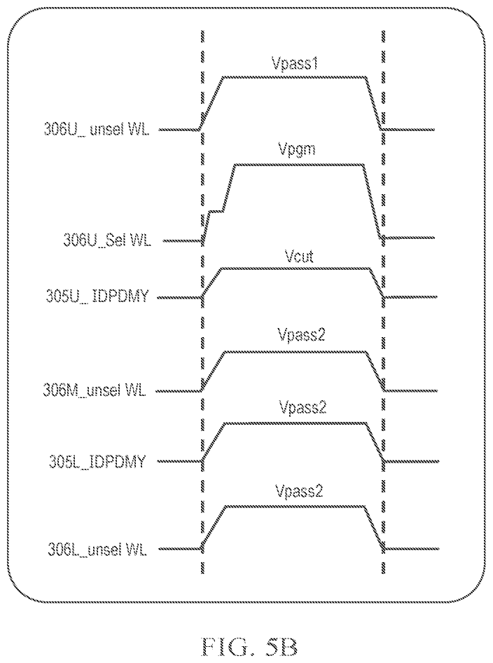

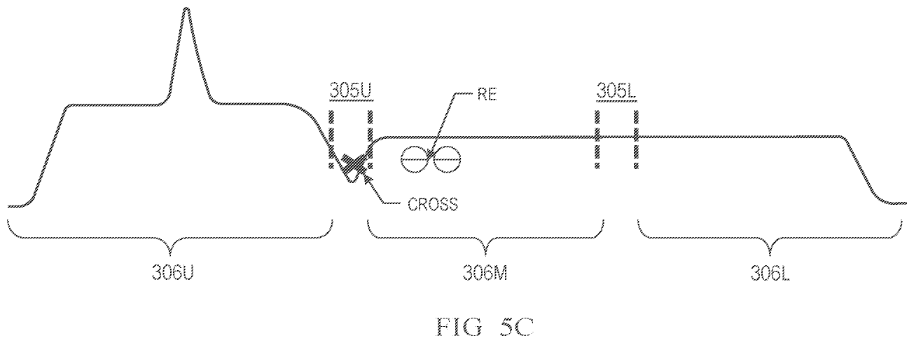

It should be noted that for details not mentioned in the various examples of the present application, for other details of the structures or components of the memory device and the operation method of the memory device, please refer to FIGS. 5A, 5B, and 5C, with reference to the relevant examples shown in FIGS. 1, 2, 3A, and 3B, which will not be repeated herc.

It should be noted that herein and below, the first memory deck represents the selected memory deck (also called the memory deck selected/select memory deck), such as the memory deck being programmed, and the second memory deck represents the unselected memory deck (also called the memory deck unselected/unselect memory deck) adjacent to the first memory deck in the vertical direction, such as the programmed unselected memory deck adjacent to the first memory deck. Referring to FIG. 4A, in the examples of the present application, the first memory deck 410 is an upper memory deck 304U which includes an upper memory layer group 306U. The second memory deck 420 is a middle memory deck 304M which includes a middle memory layer group 306M. An upper dummy memory layer group 305U is between the upper memory layer group 306U and the middle memory layer group 306M.

Referring to FIG. 4B, when programming the upper memory deck 304U separately, the program voltage Vpgm is applied to the upper memory layer group selected word line layer 306U_Sel WL of the upper memory deck 304U, the first pass voltage Vpass1 is applied to the upper memory layer group unselected word line layer 306U_unsel WL of the upper memory deck 304U, the second pass voltage Vpass2 is applied to the middle memory layer group unselected word line layer 306M_unsel WL of the middle memory deck 304M, and the voltage Vpass2˜Vpass1 between the first pass voltage and the second pass voltage is applied to the upper dummy memory layer group dummy word line layer 305U_IDPDMY, wherein the second pass voltage Vpass2 is smaller than the first pass voltage Vpass1.

Referring to FIG. 4C, when programming the upper memory deck 304U separately, the pass voltage (the second pass voltage Vpass2) of the middle memory layer group of the middle memory deck 304M is reduced to reduce the pass voltage disturbance. When programming the upper memory deck 304U separately, the pass voltage of the middle memory layer group of the middle memory deck 304M is reduced, wherein the second pass voltage Vpass2 is smaller than the first pass voltage Vpass1, which will cause a potential difference in the channel, drive the residual electrons RE in channel to migrate to the channel position corresponding to the upper memory layer group selected word line layer 306U_Sel WL of the upper memory deck 304U (the direction indicated by arrow in FIG. 4C), reduce the boosting potential of the channel corresponding to the upper memory layer group selected word line layer 306U_Sel WL of the upper memory deck 304U, and thus cause program voltage disturbance.

In the examples of this application, the unselected word line layer of the selected memory deck (the first memory deck) being programmed needs to be maintained at a higher pass voltage (the first pass voltage Vpass1) to increase the boosting potential of the selected word line layer of the selected memory deck, and to suppress program voltage disturbance; the unselected word line layer of the unselected memory deck (the second memory deck) adjacent to the selected memory deck needs to be maintained at a lower pass voltage (the second pass voltage Vpass2) to reduce pass voltage disturbance of unselected word line layers of unselected memory deck. When programming the selected memory deck separately, reducing the pass voltage (the second pass voltage Vpass2 which is smaller than the first pass voltage Vpass1) of the memory layer group of the selected memory deck will cause a potential difference in the channel, drive the channel residual electrons to migrate to the channel position corresponding to the selected word line layer of the memory layer group of the selected memory deck, and reduce the boosting potential of the channel corresponding to the selected word line layer of the memory layer group of the selected memory deck, thus cause new program voltage disturbance.

FIG. 5A is a second example programming scheme for a multi-memory deck memory device according to some examples of the present application. FIG. 5B is a schematic diagram of a signal waveform of the second example programming scheme of FIG. 5A. FIG. 5C is a schematic diagram of a channel potential of the second example programming scheme of FIG. 5A.

Referring to FIGS. 5A, 5B and 5C, and in combination with FIGS. 1, 2, 3A and 3B, the examples of this application provide a memory device 100, which comprises: a memory cell array 101 comprising a first memory deck and a second memory deck stacked and provided adjacent to each other, wherein the first memory deck and the second memory deck both comprise a plurality of memory cell layers and a word line layer 309 corresponding to each memory cell layer, and at least one dummy memory cell layer and a dummy word line layer 307 corresponding to each dummy memory cell layer are provided at a junction position of the first memory deck and the second memory deck; and a peripheral circuit 102 coupled to the memory cell array 101 and configured to: when performing a program operation on a selected memory cell layer in the first memory deck, apply a program voltage Vpgm to a word line layer corresponding to the selected memory cell layer and apply a first pass voltage Vpass1 to a word line layer corresponding to an unselected memory cell layer in the first memory deck; apply a second pass voltage Vpass2 to the word line layer corresponding to the plurality of memory cell layers in the second memory deck; and apply a third pass voltage Vcut to the dummy word line layer corresponding to the at least one dummy memory cell layer at the junction position of the first memory deck and the second memory deck, wherein the third pass voltage Vcut is less than the second pass voltage Vpass2, and the second pass voltage Vpass2 is less than the first pass voltage Vpass1.

As mentioned above, with reference to FIGS. 1 and 2, the memory device 100 may include a memory cell array 101 and a peripheral circuit 102 coupled to the memory cell array 101.

In some examples, the page buffer/sense amplifier 104 of the peripheral circuit may be configured to read data from the memory cell array 101 and program (write) data to the memory cell array 101 based on a control signal from the control logic unit 112. The row decoder/word line driver 108 of the peripheral circuit 102 may be configured to be controlled by control logic unit 112, and select/deselect the blocks 204 of memory cell array 101 and select/deselect the word lines 218 of blocks 204. The row decoder/word line driver 108 of the peripheral circuit 102 may also be configured to drive word line 218 using the word line voltage generated from voltage generator 110 to provide the signal waveform of the programming scheme. In some examples, the row decoder/word line driver 108 may also select/deselect and drive BSG line 215 and TSG line 213.

In some examples, the memory cell array 101 is a three-dimensional NAND type memory cell array as an example for illustration, wherein the memory cells are provided in the form of an array of NAND memory strings 208, and each NAND memory string 208 includes a plurality of memory cells 206 coupled in serial and stacked vertically.

As mentioned above and with reference to FIGS. 3A and 3B, in some examples, each NAND memory string 310 (corresponding to the NAND memory string 208 in FIG. 2) extends vertically above the substrate 314, and each NAND memory string 310 includes a plurality of vertically stacked word line layers 309. In some examples, each NAND memory string 310 may include a bottom selective gate at its source terminal and a top selective gate at its drain terminal, wherein a BSG line is coupled to the bottom selective gate and a TSG line is coupled to the top selective gate. The BSG line and TSG line may be configured to activate selected NAND memory strings 310 during read and program operations.

Referring to FIGS. 5A, 5B and 5C, in some examples, the word line bias voltage applied to the word line layer 309 may include the program voltage Vpgm, the pass voltage Vpass, and the third pass voltage Vcut. In some examples, during the program executing operation of the program operation, the pass voltage Vpass may be applied to the unselected word line layer, and the program voltage Vpgm may be applied to the selected word line layer, and the third pass voltage Vcut may be applied to the dummy word line layer.

In various examples of the present application, the third pass voltage Vcut may also be called soft cut voltage Vcut or cut voltage Vcut.

In some examples, the third pass voltage Vcut is less than the second pass voltage Vpass2 and less than the first pass voltage Vpass1, and the third pass voltage Vcut is greater than or equal to a first threshold which needs to be satisfied that no significant hot electron injection is triggered. A certain reduction in the third pass voltage Vcut may block the migration of residual electrons in the channel. If the third pass voltage Vcut is too low, there will be a large potential difference in the channel, causing hot electron injection, thus causing new disturbance. Therefore, the minimum value of the third pass voltage Vcut needs to be satisfied that no significant hot electron injection is triggered.

In some examples, a memory cell array may include multiple memory decks. For example, with reference to FIGS. 5A and 3B, the memory cell array includes three memory decks, including a lower memory deck 304L located above the substrate 314, a middle memory deck 304M located above the lower memory deck 304L, and an upper memory deck 304U located above the middle memory deck 304M.

Referring to FIG. 5A, in the examples of the present application, the first memory deck 410 is the upper memory deck 304U, which includes the upper memory layer group 306U; the second memory deck 420 is the middle memory deck 304M, which includes a middle memory layer group 306M; and an upper dummy memory layer group 305U is between the upper memory layer group 306U and the middle memory layer group 306M. As shown in FIG. 3B, the upper dummy memory layer group 305U is located at the junction position of the upper memory deck 304U and the middle memory deck 304M. The upper memory deck 304U includes an upper memory layer group 306U adjacent to the upper dummy memory layer group 305U, and the middle memory deck 304M includes a middle memory layer group 306M adjacent to the upper dummy memory layer group 305U, wherein the upper dummy memory layer group 305U is located between the upper memory layer group 306U and the middle memory layer group 306M.

Referring to FIG. 5B, the peripheral circuit 102 is configured to: when programming the upper memory deck 304U separately, apply the program voltage Vpgm to the upper memory layer group selected word line layer 306U_Sel WL of the upper memory deck 304U, apply the first pass voltage Vpass1 to the upper memory layer group unselected word line layer 306U_unsel WL of the upper memory deck 304U, apply the second pass voltage Vpass2 to the middle memory layer group unselected word line layer 306M_unsel WL of the middle memory deck 304M, and apply the third pass voltage Vcut to the upper dummy memory layer group dummy word line layer 305U_IDPDMY of the upper dummy memory layer group, wherein the third pass voltage Vcut is less than the second pass voltage Vpass2, and the second pass voltage Vpass2 is less than the first pass voltage Vpass1.

Referring to FIG. 5C, the peripheral circuit 102 is configured to: when programming the upper memory deck 304U separately, the pass voltage (the second pass voltage Vpass2) of the middle memory layer group of the middle memory deck 304M is reduced to reduce the pass voltage disturbance. The second pass voltage Vpass2 is less than the first pass voltage Vpass1. At the same time, the pass voltage of the upper dummy memory layer group upper dummy word line layer 305U_IDPDMY is further reduced. The third pass voltage Vcut is less than the second pass voltage Vpass2. A soft cut voltage may be formed between the upper memory layer group 306U and the middle memory layer group 306M, forming a potential barrier for the residual electrons RE, inhibiting the channel residual electrons RE from migrating to the channel position corresponding to the upper memory layer group selected word line layer 306U_Sel WL of the upper memory deck 304U (shown as a cross mark in FIG. 5C), and the channel corresponding to the upper memory layer group selected word line layer 306U_Sel WL of the upper memory deck 304U is still maintained at a higher boosting potential, thereby suppressing program voltage disturbance.

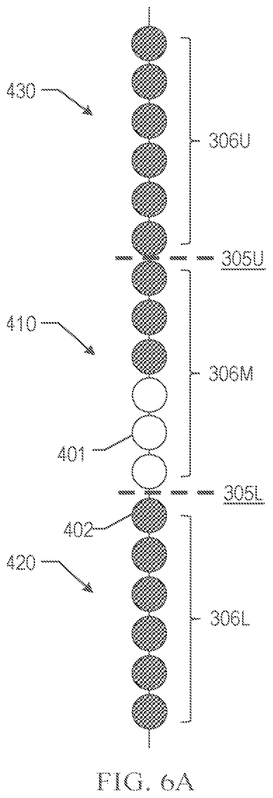

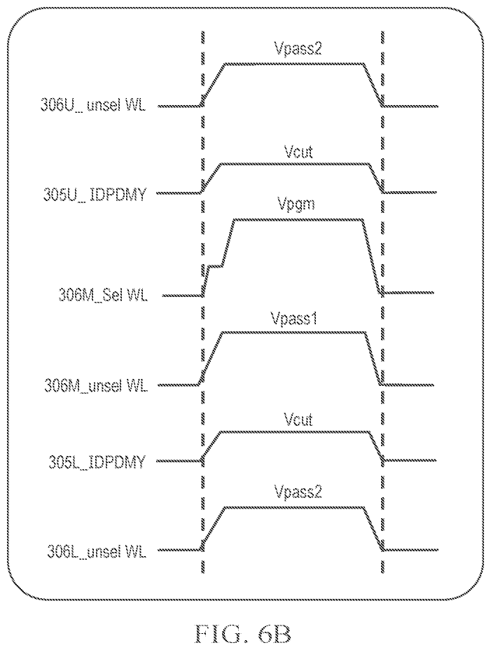

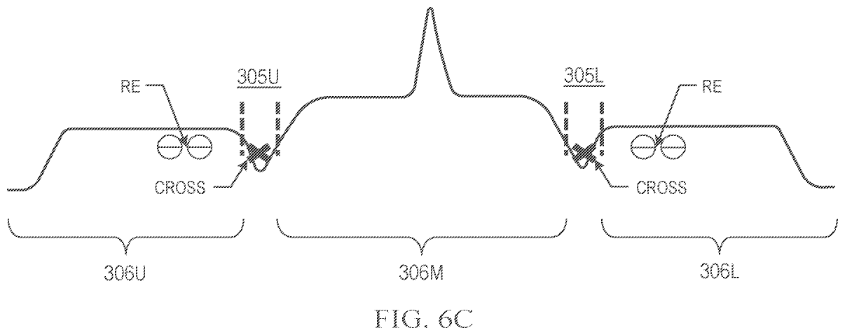

FIG. 6A is a third example programming scheme for a multi-memory deck memory device according to some examples of the present application. FIG. 6B is a schematic diagram of a signal waveform of the third example programming scheme of FIG. 6A. FIG. 6C is a schematic diagram of a channel potential of the third example programming scheme of FIG. 6A.

Referring to FIG. 6A, in the examples of the present application, the first memory deck 410 is the middle memory deck 304M, which includes the middle memory layer group 306M; the second memory deck 420 is the lower memory deck 304L, which includes a lower memory layer group 306L; and a lower dummy memory layer group 305L is between the middle memory layer group 306M and the lower memory layer group 306L. As mentioned above, as shown in FIG. 3B, the lower dummy memory layer group 305L is located at the junction position of the middle memory deck 304M and the lower memory deck 304L. The middle memory deck 304M includes a middle memory layer group 306M adjacent to the upper dummy memory layer group 305U, and the lower memory deck 304L includes an upper memory layer group 306L adjacent to the lower dummy memory layer group 305L, wherein the lower dummy memory layer group 305L is located between the middle memory layer group 306M and the lower memory layer group 306L.

Referring to FIG. 6B, the peripheral circuit 102 is configured to: when programming the middle memory deck 304M separately, apply the program voltage Vpgm to the middle memory layer group selected word line layer 306M_Sel WL of the middle memory deck 304M, apply the first pass voltage Vpass1 to the middle memory layer group unselected word line layer 306M_unsel WL of the middle memory deck 304M, apply the second pass voltage Vpass2 to the lower memory layer group unselected word line layer 306L_unsel WL of the lower memory deck 304L, and apply the third pass voltage Vcut to the lower dummy memory layer group dummy word line layer 305L_IDPDMY, wherein the third pass voltage Vcut is less than the second pass voltage Vpass2, and the second pass voltage Vpass2 is less than the first pass voltage Vpass1.

Referring to FIG. 6C, the peripheral circuit 102 is configured to: when programming the middle memory deck 304M separately, the pass voltage (the second pass voltage Vpass2) of the lower memory layer group of the lower memory deck 304L is reduced to reduce the pass voltage disturbance. The second pass voltage Vpass2 is less than the first pass voltage Vpass1. At the same time, the pass voltage of the lower dummy memory layer group dummy word line layer 305L_IDPDMY is further reduced. The third pass voltage Vcut is less than the second pass voltage Vpass2. A soft cut voltage may be formed between the middle memory layer group 306M and the lower memory layer group 306L, forming a potential barrier for the residual electrons RE, inhibiting the channel residual electrons RE from migrating to the channel position corresponding to the middle memory layer group selected word line layer 306M_Sel WL of the middle memory deck 304M (shown as a cross mark in FIG. 6C), and the channel corresponding to the middle memory layer group selected word line layer 306M_Sel WL of the middle memory deck 304M is still maintained at a higher boosting potential, thereby suppressing program voltage disturbance.

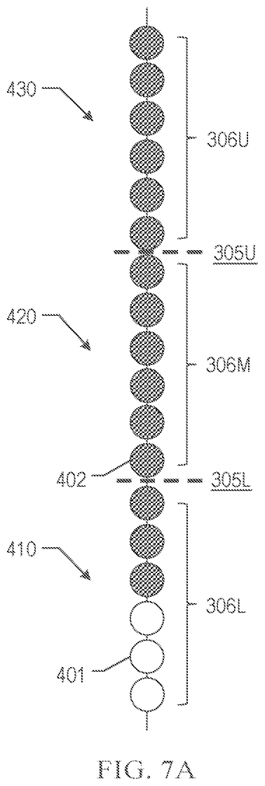

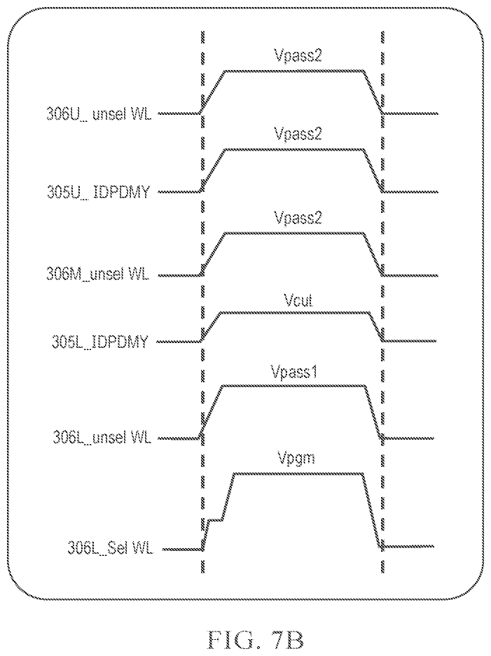

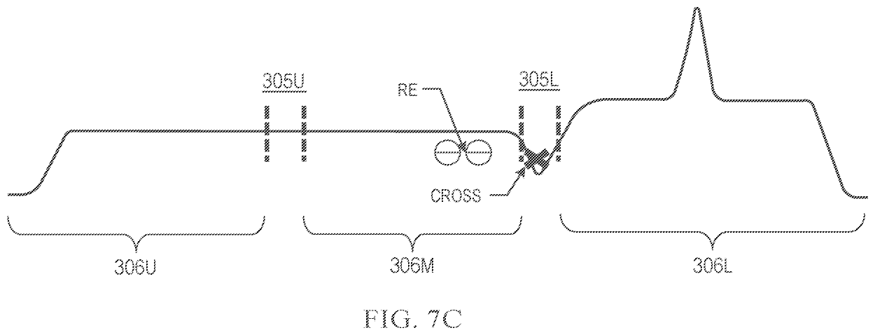

FIG. 7A is a fourth example programming scheme for a multi-memory deck memory device according to some examples of the present application. FIG. 7B is a schematic diagram of a signal waveform of the fourth example programming scheme of FIG. 7A. FIG. 7C is a schematic diagram of a channel potential of the fourth example programming scheme of FIG. 7A.

Referring to FIG. 7A, in the examples of the present application, the first memory deck 410 is the lower memory deck 304L, which includes the lower memory layer group 306L; the second memory deck 420 is the middle memory deck 304M, which includes a middle memory layer group 306M; and a lower dummy memory layer group 305L is between the lower memory layer group 306L and the middle memory layer group 306M.

Referring to FIG. 7B, the peripheral circuit 102 is configured to: when programming the lower memory deck 304L separately, apply the program voltage Vpgm to the lower memory layer group selected word line layer 306L_Sel WL of the lower memory deck 304L, apply the first pass voltage Vpass1 to the lower memory layer group unselected word line layer 306L_unsel WL of the lower memory deck 304L, apply the second pass voltage Vpass2 to the middle memory layer group unselected word line layer 306M_unsel WL of the middle memory deck 304M, and apply the third pass voltage Vcut to the lower dummy memory layer group dummy word line layer 305L_IDPDMY, wherein the third pass voltage Vcut is less than the second pass voltage Vpass2, and the second pass voltage Vpass2 is less than the first pass voltage Vpass1.

Referring to FIG. 7C, the peripheral circuit 102 is configured to: when programming the lower memory deck 304L separately, the pass voltage (the second pass voltage Vpass2) of the middle memory layer group of the middle memory deck 304M is reduced to reduce the pass voltage disturbance. The second pass voltage Vpass2 is less than the first pass voltage Vpass1. At the same time, the pass voltage of the lower dummy memory layer group dummy word line layer 305L_IDPDMY is further reduced. The third pass voltage Vcut is less than the second pass voltage Vpass2. A soft cut voltage may be formed between the lower memory layer group 306L and the middle memory layer group 306M, forming a potential barrier for the residual electrons RE, inhibiting the channel residual electrons RE from migrating to the channel position corresponding to the lower memory layer group selected word line layer 306L_Sel WL of the lower memory deck 304L (shown as a cross mark in FIG. 7C), and the channel corresponding to the lower memory layer group selected word line layer 306L_Sel WL of the lower memory deck 304L is still maintained at a higher boosting potential, thereby suppressing program voltage disturbance.

Referring to FIGS. 6A, 6B and 6C, and in combination with FIGS. 1, 2, 3A and 3B, in some examples, the memory cell array further comprises a third memory deck 430 stacked with both the first memory deck 410 and the second memory deck 420; the third memory deck 430 is provided adjacent to the first memory deck 410, at least one dummy memory cell layer and a dummy word line layer corresponding to each dummy memory cell layer are provided at the junction position of the third memory deck 430 and the first memory deck 410; the peripheral circuit is configured to apply the third pass voltage Vcut to the dummy word line layer corresponding to the at least one dummy memory cell layer at the junction position of the first memory deck 410 and the third memory deck 430.

Referring to FIG. 6A, in the examples of the present application, the first memory deck 410 is the middle memory deck 304M, which includes the middle memory layer group 306M; the second memory deck 420 is the lower memory deck 304L, which includes a lower memory layer group 306L; and the third memory deck 430 is the upper memory deck 304U, which includes an upper memory layer group 306U; an upper dummy memory layer group 305U is between the upper memory layer group 306U and the middle memory layer group 306M, and a lower dummy memory layer group 305L is between the middle memory layer group 306M and the lower memory layer group 306L.

Referring to FIG. 6B, the peripheral circuit 102 is configured to: when programming the middle memory deck 304M separately, apply the program voltage Vpgm to the middle memory layer group selected word line layer 306M_Sel WL of the middle memory deck 304M, apply the first pass voltage Vpass1 to the middle memory layer group unselected word line layer 306M_unsel WL of the middle memory deck 304M, apply the second pass voltage Vpass2 to the lower memory layer group unselected word line layer 306L_unsel WL of the lower memory deck 304L, and apply the third pass voltage Vcut to the lower dummy memory layer group dummy word line layer 305L_IDPDMY, apply the second pass voltage Vpass2 to the upper memory layer group unselected word line 306_unsel WL of the upper memory deck 304U, and apply the third pass voltage Vcut to the upper dummy memory layer group dummy word line layer 305U_IDPDMY, wherein the third pass voltage Vcut is less than the second pass voltage Vpass2, and the second pass voltage Vpass2 is less than the first pass voltage Vpass1.

In other examples, the first memory deck is the middle memory deck 304M, which includes the middle memory layer group 306M; the second memory deck is the upper memory deck 304U, which includes an upper memory layer group 306U; and the third memory deck 430 is the lower memory deck 304L, which includes a lower memory layer group 306L; an upper dummy memory layer group 305U is between the upper memory layer group 306U and the middle memory layer group 306M, and a lower dummy memory layer group 305L is between the middle memory layer group 306M and the lower memory layer group 306L. In this case, the signal waveform of the example programming scheme may be understood with reference to FIG. 6B, and the channel potential of the example programming scheme may be understood with reference to FIG. 6C, which will not be repeated here.

Referring to FIGS. 7A, 7B, 7C, and in combination with FIGS. 1, 2, 3A and 3B, in some examples, the memory cell array further comprises: a third memory deck 430 stacked with both the first memory deck 410 and the second memory deck 420; the third memory deck 430 is provided adjacent to the second memory deck 420, at least one dummy memory cell layer and a dummy word line layer corresponding to each dummy memory cell layer are provided at the junction position of the third memory deck 430 and the second memory deck 420; and the peripheral circuit is configured to apply the second pass voltage Vpass2 to the dummy word line layer corresponding to the at least one dummy memory cell layer at the junction position of the second memory deck 420 and the third memory deck 430.

Referring to FIG. 7A, in the examples of the present application, the first memory deck 410 is the lower memory deck 304L, which includes the lower memory layer group 306; the second memory deck 420 is the middle memory deck 304M, which includes a middle memory layer group 306M; the third memory deck 430 is the upper memory deck 304U, which includes an upper memory layer group 306U; an upper dummy memory layer group 305U is between the upper memory layer group 306U and the middle memory layer group 306M, and a lower dummy memory layer group 305L is between the middle memory layer group 306M and the lower memory layer group 306L.

Referring to FIG. 7B, the peripheral circuit 102 is configured to: when programming the lower memory deck 304L separately, apply the program voltage Vpgm to the lower memory layer group selected word line layer 306L_Sel WL of the lower memory deck 304L, apply the first pass voltage Vpass1 to the lower memory layer group unselected word line layer 306L_unsel WL of the lower memory deck 304L, apply the second pass voltage Vpass2 to the middle memory layer group unselected word line layer 306M_unsel WL of the middle memory deck 304M, and apply the third pass voltage Vcut to the lower dummy memory layer group dummy word line layer 305L_IDPDMY, apply the second pass voltage Vpass2 to the upper memory layer group unselected word line 306U_unsel WL of the upper memory deck 304U, and apply the second pass voltage Vpass2 to the upper dummy memory layer group dummy word line layer 305U_IDPDMY, wherein the third pass voltage Vcut is less than the second pass voltage Vpass2, and the second pass voltage Vpass2 is less than the first pass voltage Vpass1.

In other examples, the first memory deck is the lower memory deck 304L, which includes the lower memory layer group 306L; the second memory deck is the upper memory deck 304U, which includes an upper memory layer group 306U; and the third memory deck is the middle memory deck 304M, which includes a middle memory layer group 306M; an upper dummy memory layer group 305U is between the upper memory layer group 306U and the middle memory layer group 306M, and a lower dummy memory layer group 305L is between the middle memory layer group 306M and the lower memory layer group 306L. In this case, the signal waveform of the example programming scheme may be understood with reference to FIG. 7B, and the channel potential of the example programming scheme may be understood with reference to FIG. 7C, which will not be repeated here.

In some examples, a difference between the first pass voltage and the second pass voltage is a first difference, and a difference between the second pass voltage and the third pass voltage is a second difference, wherein the first difference is different from the second difference.

In some examples, when the second difference is greater than the first difference, a larger potential barrier may be formed for the channel residual electrons corresponding to the unselected word line layer of the memory layer group of the unselected memory deck.

As shown in FIGS. 5A, 6A and 7A, in some examples, multiple memory cell layers in the second memory deck 420 are all in the programmed state 402. In some examples, as shown in FIG. 6A, multiple memory cell layers in the second memory deck 420 are all in the programmed state 402 and multiple memory cell layers in the third memory deck 430 are all in the programmed state 402.

In the examples of the present application, the down coupled residual electrons in the channel corresponding to the unselected word line layer of the unselected memory deck (programmed memory deck) are blocked from migrating to the lower portion of the channel corresponding to the selected word line layer of the memory layer group of the selected memory deck (the memory deck being programmed), so that the channel corresponding to the selected word line layer of the memory layer group of the selected memory deck is still maintained at a higher boosting potential to suppress program voltage disturbance.

As shown in FIGS. 5A, 6A and 7A, in some examples, the unselected memory cell layer in the first memory deck 410 comprises a memory cell layer in a programmed state 402 and a memory cell layer in an erased state 401, and the first pass voltage comprises a first sub-pass voltage and a second sub-pass voltage, wherein the peripheral circuit is configured to: apply the first sub-pass voltage to a word line layer corresponding to the memory cell layer in the programmed state; and apply the second sub-pass voltage to a word line layer corresponding to the memory cell layer in the erased state, wherein the first sub-pass voltage is different from the second sub-pass voltage.

In some examples, the first sub-pass voltage is greater than the second sub-pass voltage.

In the examples of the present application, the threshold voltage of the memory cell layer in the programmed state 402 is higher than that of the memory cell layer in the erased state 401. The pass voltage applied to the word line layer corresponding to the memory cell layer in the erased state may be greater than the pass voltage applied to the word line layer corresponding to the memory cell layer in the erased state, i.e., the first sub-pass voltage is greater than the second sub-pass voltage, so that the channel corresponding to the selected word line layer of the memory layer group of the selected memory deck is still maintained at a higher boosting potential to suppress the program voltage disturbance.

It is noted that the number of memory cell layers (or word line layers) of each memory deck shown in FIGS. 4A, 5A, 6A and 7A is for illustration only and is not intended to limit the number of memory cell layers (or word line layers) of each memory deck to 6 in the examples of the present application. The number of dummy memory cell layers (or dummy word line layers) of each memory deck shown in FIGS. 4A, 5A, 6A and 7A is for illustration only and is not intended to limit the number of memory cell layers (or dummy word line layers) of each memory deck to 1 in the examples of the present application.

In some examples, the at least one dummy memory cell layer and the dummy word line layer corresponding to each dummy memory cell layer at the junction position of the first memory deck and the second memory deck belong to at least one of the first memory deck or the second memory deck.

In examples of the present application, the dummy memory layer group may include at least one dummy memory cell layer and a dummy word line layer corresponding to each dummy memory cell layer. The dummy memory layer group may be located in at least one of adjacent memory decks.

In some examples, the dummy memory layer group may include multiple memory cell layers and a word line layer corresponding to each memory cell layer. A part of the dummy memory layer group is located in one memory deck, and the other part is located in another memory deck. For example, the lower dummy memory layer group 305L shown in FIG. 3A may include a dummy memory cell layer located in the lower memory deck 304L and a dummy word line layer 307 corresponding to a dummy memory cell layer, and a dummy memory cell layer located in the upper memory deck 304U and a dummy word line layer 307 corresponding to a dummy memory cell layer. For example, with reference to FIG. 3B, and in combination with reference to FIGS. 4A, 5A, 6A and 7A, the lower dummy memory layer group 305L may include a memory cell layer located in the lower memory deck 304L and a word line layer corresponding to each memory cell layer, as well as a memory cell layer located in the middle memory deck 304M and a word line layer 309 corresponding to each memory cell layer. Alternatively, with reference to FIG. 3B, and in combination with reference to FIGS. 4A, 5A, 6A and 7A, the upper dummy memory layer group 305U may include a memory cell layer located in the middle memory deck 304M and a word line layer 309corresponding to each memory cell layer, and a memory cell layer located in the upper memory deck 304U and a word line layer 309 corresponding to each memory cell layer.

In some examples, the at least one dummy word line layer at the junction position of the first memory deck and the second memory deck comprises a first dummy word line layer located in the first memory deck and a second dummy word line layer located in the second memory deck, and the third pass voltage comprises a third sub-pass voltage and a fourth sub-pass voltage, wherein the peripheral circuit is configured to apply the third sub-pass voltage to the first dummy word line layer and apply the fourth sub-pass voltage to the second dummy word line layer, wherein the third sub-pass voltage is different from the fourth sub-pass voltage.

In some examples, the third sub-pass voltage is greater than the fourth sub-pass voltage.

In the examples of the present application, in order to increase the potential barrier between the second dummy word line layer in the second memory deck and the word line layer to which the second pass voltage Vpass2 is applied in the second memory deck, the difference between the second pass voltage Vpass2 applied to the second memory deck word line layer and the fourth sub-pass voltage applied to the second dummy word line layer is increased as much as possible. At the same time, in order to avoid the potential barrier between the first dummy word line located in the first memory deck and the word line layer to which the first pass voltage Vpass1 is applied in the first memory deck being too large, the difference between the first pass voltage Vpass1 applied to the first memory deck word line layer and three sub-pass voltages applied to the first dummy word line is reduced as much as possible, and the third sub-pass voltage applied to the first dummy word line layer may be set to be greater than the fourth sub-pass voltage applied to the second dummy word line layer; the third sub-pass voltage and the fourth sub-pass voltage are both smaller than the second pass voltage Vpass2. In the examples of the present application, the down coupled residual electrons in the channel corresponding to the unselected word line layer of the programmed memory deck are blocked from migrating to the lower part of the channel corresponding to the selected word line layer of the memory layer group of the selected memory deck, so that the channel corresponding to the selected word line layer of the memory layer group of the selected memory deck is still maintained at a higher boosting potential to suppress program voltage disturbance.

In some examples, the peripheral circuit is configured to: when performing a program operation on the plurality of memory cell layers in the first memory deck, perform a sequential program operation or a reversed program operation on the plurality of memory cell layers in the first memory deck. For example, as shown in FIGS. 5A, 6A and 7A, the peripheral circuit is configured to perform sequential program operations on a plurality of memory cell layers in the first memory deck, i.e., in the direction from the memory cell layer of the drain selective transistor close to NAND memory string 310 to the memory cell layer of the drain selective transistor away from NAND memory string 310, the program operations are performed on each memory cell layer in the first memory deck in sequence.

In various examples of the present application, a memory device includes a first memory deck and a second memory deck provided adjacent to each other. When the PER operation is independently performed on the selected memory deck (the first memory deck), the unselected word line layer of the selected memory deck needs to be maintained at a higher pass voltage (the first pass voltage Vpass1) to increase the boosting potential of the selected word line layer of the selected memory deck, thus to suppress program voltage disturbance. The unselected word line layer of the unselected memory deck (the second memory deck) needs to be maintained at a lower pass voltage (the second pass voltage Vpass2 which is smaller than the first pass voltage Vpass1) to reduce the pass voltage disturbance of the unselected word line layer of the unselected memory deck. Meanwhile, the pass voltage (the third pass voltage Vcut which is smaller than the second pass voltage Vpass2) of the dummy memory layer group at the junction position adjacent to the selected memory deck is further reduced, thus a soft cut voltage may be formed between the memory layer group of the selected memory deck and the memory layer group of the unselected memory deck adjacent to the selected memory deck, and a potential barrier for the channel residual electrons RE is formed to suppress the migration of the channel residual electrons RE to the channel position corresponding to the selected word line layer of the memory layer group of the selected memory deck, so that a higher boosting potential is maintained in the channel corresponding to the selected word line layer of the memory layer group of the selected memory deck to suppress the program voltage disturbance. That is, in the examples of the present application, when the PER operation is independently performed on each memory deck, the pass voltage disturbance of the unselected memory deck is reduced while the program voltage disturbance of the selected memory deck is suppressed.

The examples of the present application provide an operation method of a memory device, comprising: when performing a program operation on a selected memory cell layer in a first memory deck of a memory cell array of the memory device, applying a program voltage to a word line layer corresponding to the selected memory cell layer and applying a first pass voltage to a word line layer corresponding to an unselected memory cell layer in the first memory deck; applying a second pass voltage to a word line layer corresponding to a plurality of memory cell layers in a second memory deck which is stacked and provided adjacent to the first memory deck; and applying a third pass voltage to a dummy word line layer corresponding to at least one dummy memory cell layer at a junction position of the first memory deck and the second memory deck, wherein the third pass voltage is less than the second pass voltage, and the second pass voltage is less than the first pass voltage.

In some examples, the unselected memory cell layer in the first memory deck comprises a memory cell layer in a programmed state and a memory cell layer in an erased state, and the first pass voltage comprises a first sub-pass voltage and a second sub-pass voltage, wherein the applying a first pass voltage to a word line layer corresponding to an unselected memory cell layer in the first memory deck comprises: applying the first sub-pass voltage to a word line layer corresponding to the memory cell layer in the programmed state; and applying the second sub-pass voltage to a word line layer corresponding to the memory cell layer in the erased state, wherein the first sub-pass voltage is different from the second sub-pass voltage.

In some examples, the memory cell array comprises a third memory deck stacked with both the first memory deck and the second memory deck, wherein when the third memory deck is provided adjacent to the first memory deck, at least one dummy memory cell layer and a dummy word line layer corresponding to each dummy memory cell layer are provided at a junction position of the third memory deck and the first memory deck, and applying a third pass voltage to a dummy word line layer corresponding to at least one dummy memory cell layer at a junction position of the first memory deck and the second memory deck comprises: applying the third pass voltage to the dummy word line layer corresponding to the at least one dummy memory cell layer at the junction position between the first memory deck and the third memory deck; or when the third memory deck is provided adjacent to the second memory deck, at least one dummy memory cell layer and a dummy word line layer corresponding to each dummy memory cell layer are provided at a junction position of the third memory deck and the second memory deck, and applying a third pass voltage to a dummy word line layer corresponding to at least one dummy memory cell layer at a junction position of the first memory deck and the second memory deck comprises applying the second pass voltage to the dummy word line layer corresponding to the at least one dummy memory cell layer at the junction position between the second memory deck and the third memory deck.

In some examples, the at least one dummy word line layer at the junction position of the first memory deck and the second memory deck comprises a first dummy word line layer located in the first memory deck and a second dummy word line layer located in the second memory deck, and the third pass voltage comprises a third sub-pass voltage and a fourth sub-pass voltage, wherein the applying a third pass voltage to a dummy word line layer corresponding to at least one dummy memory cell layer at a junction position of the first memory deck and the second memory deck comprises: applying the third sub-pass voltage to the first dummy word line layer and applying the fourth sub-pass voltage to the second dummy word line layer, wherein the third sub-pass voltage is different from the fourth sub-pass voltage.

In some examples, the method further comprises: when performing a program operation on the plurality of memory cell layers in the first memory deck, performing a sequential program operation or a reversed program operation on the plurality of memory cell layers in the first memory deck.

The memory device to which the operation method of the memory device provided in the examples of the present application is applied is similar to the memory device in the above mentioned examples. For technical features not disclosed in details in the examples of the present application, please refer to the above mentioned memory device side examples, which will not be repeated here.

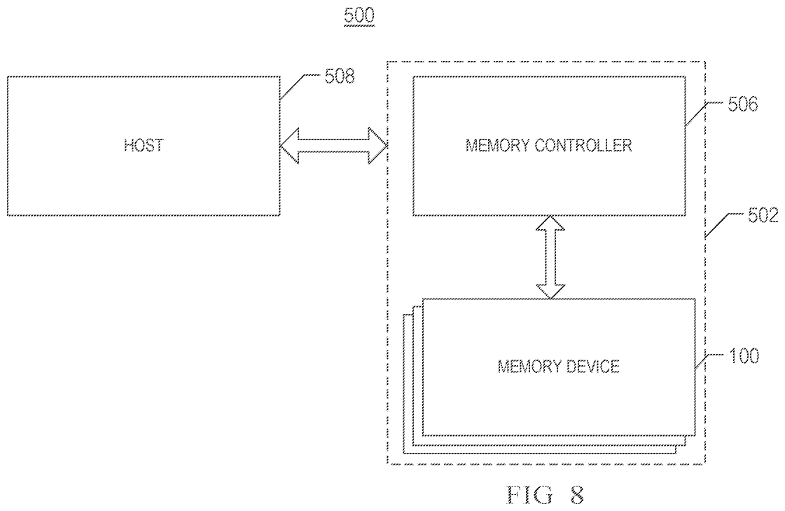

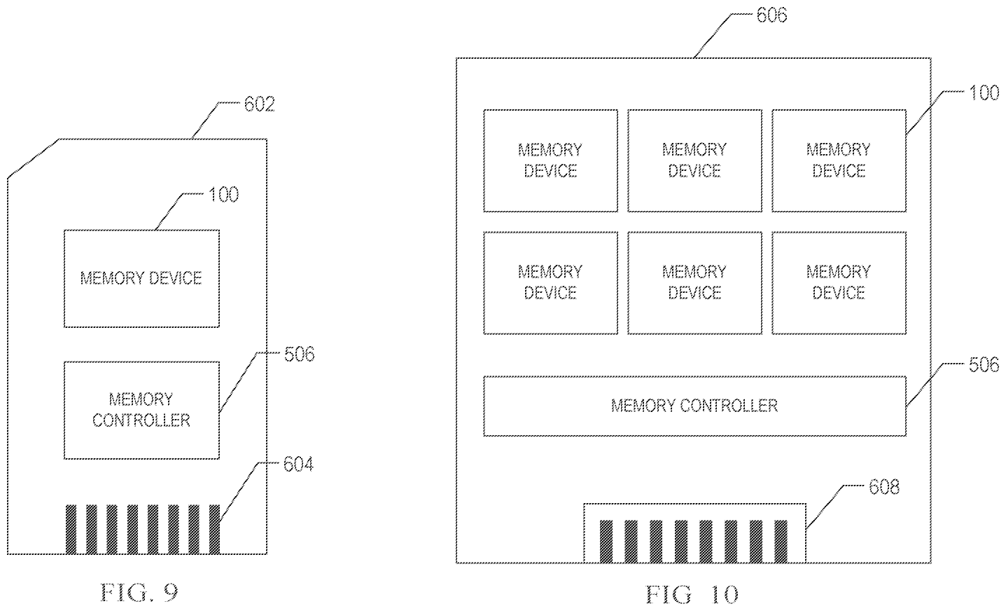

FIG. 8 is a schematic diagram of an example system having a memory system according to an example of the present application. FIG. 9 is a schematic diagram of an example memory card having a memory system according to an example of the present application. FIG. 10 is a schematic diagram of an example solid-state driver having a memory system according to an example of the present application.

Referring to FIGS. 8, 9 and 10, the examples of the present application provide a memory system comprising: one or more memory devices 100 of any of the above examples; and a memory controller coupled to the memory devices 100 and configured to control the memory devices 100.

In one example in FIG. 8, the system 500 may be a mobile phone, desktop computer, laptop computer, tablet computer, vehicle computer, game console, printer, positioning device, wearable electronic device, smart sensor, virtual reality (VR) device, augmented reality (AR) device or any other suitable electronic device having storage therein. As shown in FIG. 8, the system 500 may include a host system 508 and a memory system 502 having one or more memory devices 100 and a memory controller 506. The host 508 may be a processor of an electronic device (e.g., a central processing unit (CPU)) or a system-on-chip (SoC) (e.g., an application processor (AP)). The host 508 may be configured to send data to or receive data from memory device 100.

The memory device 100 may be any memory set forth in this application. As explained in detail below, the memory device 100 (e.g., NAND flash memory (e.g., three-dimensional (3D) NAND flash memory)) may have a reduced leakage current from a drive transistor (e.g., the string driver) coupled to an unselected word line during an crase operation, which allows for further reduction in the size of the drive transistor.

The memory controller 506 is coupled to the memory device 100 and host 508 and is configured to control memory device 100 according to some examples. The memory controller 506 may manage data stored in the memory device 100 and communicate with the host 508. In some examples, the memory controller 506 is designed to operate in low duty cycles, such as a secure digital (SD) card, compact flash (CF) card, universal serial bus (USB) flash drive or other media for use in electronic devices such as personal computers, digital cameras, mobile phones, and the like. In some examples, the memory controller 506 is designed to operate in a high duty cycle environment SSD or embedded multimedia card (eMMC), wherein the SSD or eMMC are used as a data storage for mobile devices such as smart phones, tablet computers, laptops, and the like, and enterprise storage array.

The memory controller 506 may be configured to control operations of the memory device 100, such as read, erase and program operations. The memory controller 506 may also be configured to manage various functions relating to data stored or to be stored in the memory device 100, including, but not limited to, bad block management, garbage collection, logic to physical address translation, wear leveling, and the like. In some examples, the memory controller 506 is further configured to process error correction codes (ECC) regarding data read from or written to the memory device 100. The memory controller 506 may also perform any other function such as formatting the memory device 100. The memory controller 506 may communicate with an external device (e.g., host 508) according to a particular communication protocol. For example, the memory controller 506 may communicate with the external device through at least one of various interface protocols, such as USB protocol, MMC protocol, peripheral component interconnect (PCI) protocol, PCI-express (PCI-E) protocol, advanced technology attachment (ATA) protocol, serial ATA protocol, parallel ATA protocol, small computer small interface (SCSI) protocol, enhanced small disk interface (ESDI) protocol, integrated drive electronic device (IDE) protocol, firmware protocol, and the like.

The memory controller 506 and one or more memory devices 100 may be integrated into various types of memory devices, e.g., included in the same package (e.g., universal flash storage (UFS) package or eMMC package). That is, the memory system 502 may be implemented and packaged in different types of terminal electronics.

In an example as shown in FIG. 9, the memory controller 506 and a single memory device 100 may be integrated into the memory card 602. The memory card 602 may include a PC card (PCMCIA, Personal Computer Memory Card International Association), CF card, a smart media (SM) card, a memory stick, a multimedia card (MMC, RS-MMC, MMCmicro), a SD card (SD, miniSD, microSD, SDHC), a UFS, and the like. The memory card 602 may also include a memory card connector 604 that couples the memory card 602 to a host (e.g., host 508 in FIG. 8).

In another example as shown in FIG. 10, the memory controller 506 and a plurality of memory devices 100 may be integrated into the SSD 606. The SSD 606 may also include an SSD connector 608 that couples the SSD 606 to a host (e.g., host 508 in FIG. 8). In some examples, at least one of the storage capacity or operating speed of the SSD 606 is greater than that of the memory card 602 (as shown in FIG. 9).

Features disclosed in several method or device examples provided herein may be arbitrarily combined to get new method or device examples without conflicting.

Those of ordinary skill in the art will appreciate that the above examples are examples which realize the present application, which may be varied in form and detail in practical application without departing from the spirit and scope of the present application. Any variation or permutation readily contemplated by those skilled in the art within the scope of the present disclosure should be covered within the scope of protection of the present disclosure.

What is claimed is:

1. A memory device comprising:
a memory cell array comprising a first memory deck and a second memory deck stacked with each other, wherein the first memory deck and the second memory deck both comprise a plurality of memory cell layers and a word line layer corresponding to each memory cell layer, and at least one dummy memory cell layer and a dummy word line layer corresponding to each dummy memory cell layer are provided at a junction position of the first memory deck and the second memory deck; and
a peripheral circuit coupled to the memory cell array and configured to:
when performing a program operation on a selected memory cell layer in the first memory deck, apply a program voltage to a word line layer corresponding to the selected memory cell layer and apply a first pass voltage to a word line layer corresponding to an unselected memory cell layer in the first memory deck;
apply a second pass voltage to the word line layer corresponding to the plurality of memory cell layers in the second memory deck; and
apply a third pass voltage to the dummy word line layer corresponding to the at least one dummy memory cell layer at the junction position of the first memory deck and the second memory deck, wherein
the third pass voltage is less than the second pass voltage, and the second pass voltage is less than the first pass voltage.

2. The memory device of claim 1, wherein a difference between the first pass voltage and the second pass voltage is a first difference, and a difference between the second pass voltage and the third pass voltage is a second difference, wherein the first difference is different from the second difference.

3. The memory device of claim 2, wherein the second difference is greater than the first difference.

4. The memory device of claim 1, wherein the plurality of memory cell layers in the second memory deck are in a programmed state.

5. The memory device of claim 1, wherein the unselected memory cell layer in the first memory deck comprises a memory cell layer in a programmed state and a memory cell layer in an erased state, and the first pass voltage comprises a first sub-pass voltage and a second sub-pass voltage, wherein
the peripheral circuit is configured to:
apply the first sub-pass voltage to a word line layer corresponding to the memory cell layer in the programmed state; and
apply the second sub-pass voltage to a word line layer corresponding to the memory cell layer in the erased state, wherein
the first sub-pass voltage is different from the second sub-pass voltage.

6. The memory device of claim 1, wherein the memory cell array further comprises a third memory deck stacked with both the first memory deck and the second memory deck, wherein
the third memory deck is stacked with the first memory deck, at least one dummy memory cell layer and a dummy word line layer corresponding to each dummy memory cell layer are provided at a junction position of the third memory deck and the first memory deck, and the peripheral circuit is configured to apply the third pass voltage to the dummy word line layer corresponding to the at least one dummy memory cell layer at the junction position between the first memory deck and the third memory deck.

7. The memory device of claim 1, wherein the at least one dummy memory cell layer and the dummy word line layer corresponding to each dummy memory cell layer at the junction position of the first memory deck and the second memory deck belong to at least one of the first memory deck or the second memory deck.

8. The memory device of claim 7, wherein the at least one dummy word line layer at the junction position of the first memory deck and the second memory deck comprises a first dummy word line layer located in the first memory deck and a second dummy word line layer located in the second memory deck, and the third pass voltage comprises a third sub-pass voltage and a fourth sub-pass voltage, wherein
the peripheral circuit is configured to apply the third sub-pass voltage to the first dummy word line layer and apply the fourth sub-pass voltage to the second dummy word line layer, wherein the third sub-pass voltage is different from the fourth sub-pass voltage.

9. The memory device of claim 1, wherein the peripheral circuit is configured to:
when performing a program operation on the plurality of memory cell layers in the first memory deck, perform one of a sequential program operation or a reversed program operation on the plurality of memory cell layers in the first memory deck.

10. The memory device of claim 1, wherein the third memory deck is provided adjacent to the second memory deck, at least one dummy memory cell layer and a dummy word line layer corresponding to each dummy memory cell layer are provided at a junction position of the third memory deck and the second memory deck, and the peripheral circuit is configured to apply the second pass voltage to the dummy word line layer corresponding to the at least one dummy memory cell layer at the junction position between the second memory deck and the third memory deck.

11. A memory system comprising:
one or more memory devices, each of the memory devices comprising:
a memory cell array comprising a first memory deck and a second memory deck stacked with each other, wherein the first memory deck and the second memory deck both comprise a plurality of memory cell layers and a word line layer corresponding to each memory cell layer, and at least one dummy memory cell layer and a dummy word line layer corresponding to each dummy memory cell layer are provided at a junction position of the first memory deck and the second memory deck; and
a peripheral circuit coupled to the memory cell array and configured to:
when performing a program operation on a selected memory cell layer in the first memory deck, apply a program voltage to a word line layer corresponding to the selected memory cell layer and apply a first pass voltage to a word line layer corresponding to an unselected memory cell layer in the first memory deck;
apply a second pass voltage to the word line layer corresponding to the plurality of memory cell layers in the second memory deck; and
apply a third pass voltage to the dummy word line layer corresponding to the at least one dummy memory cell layer at the junction position of the first memory deck and the second memory deck, wherein
the third pass voltage is less than the second pass voltage, and the second pass voltage is less than the first pass voltage; and
a memory controller coupled to the one or more memory devices and configured to control the one or more memory devices.

12. An operation method of a memory device, comprising:
when performing a program operation on a selected memory cell layer in a first memory deck of a memory cell array of the memory device, applying a program voltage to a word line layer corresponding to the selected memory cell layer and applying a first pass voltage to a word line layer corresponding to an unselected memory cell layer in the first memory deck;
applying a second pass voltage to a word line layer corresponding to a plurality of memory cell layers in a second memory deck which is stacked with the first memory deck; and
applying a third pass voltage to a dummy word line layer corresponding to at least one dummy memory cell layer at a junction position of the first memory deck and the second memory deck, wherein
the third pass voltage is less than the second pass voltage, and the second pass voltage is less than the first pass voltage.

13. The operation method of claim 12, wherein the unselected memory cell layer in the first memory deck comprises a memory cell layer in a programmed state and a memory cell layer in an erased state, and the first pass voltage comprises a first sub-pass voltage and a second sub-pass voltage, wherein
the applying a first pass voltage to a word line layer corresponding to an unselected memory cell layer in the first memory deck comprises:
applying the first sub-pass voltage to a word line layer corresponding to the memory cell layer in the programmed state; and
applying the second sub-pass voltage to a word line layer corresponding to the memory cell layer in the erased state, wherein
the first sub-pass voltage is different from the second sub-pass voltage.

14. The operation method of claim 12, wherein the memory cell array comprises a third memory deck stacked with both the first memory deck and the second memory deck, wherein
when the third memory deck is provided stacked with the first memory deck, at least one dummy memory cell layer and a dummy word line layer corresponding to each dummy memory cell layer are provided at a junction position of the third memory deck and the first memory deck, and the operation method further comprises applying the third pass voltage to the dummy word line layer corresponding to the at least one dummy memory cell layer at the junction position between the first memory deck and the third memory deck.

15. The operation method of claim 12, wherein the at least one dummy word line layer at the junction position of the first memory deck and the second memory deck comprises a first dummy word line layer located in the first memory deck and a second dummy word line layer located in the second memory deck, and the third pass voltage comprises a third sub-pass voltage and a fourth sub-pass voltage, wherein
the applying a third pass voltage to a dummy word line layer corresponding to at least one dummy memory cell layer at a junction position of the first memory deck and the second memory deck comprises:
applying the third sub-pass voltage to the first dummy word line layer and applying the fourth sub-pass voltage to the second dummy word line layer, wherein the third sub-pass voltage is different from the fourth sub-pass voltage.

16. The operation method of claim 12, wherein the method further comprises:
when performing a program operation on the plurality of memory cell layers in the first memory deck, performing one of a sequential program operation or a reversed program operation on the plurality of memory cell layers in the first memory deck.

17. The operation method of claim 12, wherein, when the third memory deck is provided adjacent to the second memory deck, at least one dummy memory cell layer and a dummy word line layer corresponding to each dummy memory cell layer are provided at a junction position of the third memory deck and the second memory deck, and the operation method further comprises applying the second pass voltage to the dummy word line layer corresponding to the at least one dummy memory cell layer at the junction position between the second memory deck and the third memory deck.
